(19) United States
(12) Patent Application Publication
(10) Pub. No.: US 2024/0079394 A1
(43) Pub. Date: Mar. 7, 2024

(54) SEMICONDUCTOR PACKAGE

(71) Applicant: Samsung Electronics Co., Ltd., Suwon-si (KR)

(72) Inventors: Juil CHOI, Suwon-si (KR); Jongho PARK, Suwon-si (KR); Sanghyuck OH, Suwon-si (KR); Jaeyoung LEE, Suwon-si (KR); Jaemok JUNG, Suwon-si (KR); Hongseo HEO, Suwon-si (KR)

(73) Assignee: Samsung Electronics Co., Ltd., Suwon-si (KR)

(21) Appl. No.: 18/366,054

(22) Filed: Aug. 7, 2023

(30) Foreign Application Priority Data
Sep. 5, 2022 (KR) 10-2022-0112173

(51) Int. Cl. H01L 25/10; H01L 23/00; H01L 23/31; H01L 23/373; H01L 23/48; H01L 23/498; H10B 80/00

(52) U.S. Cl. CPC H01L 25/105; H01L 23/3128; H01L 23/3736; H01L 23/481; H01L 23/49811; H01L 23/49822; H01L 24/16; H01L 24/32; H10B 80/00; H01L 24/73; H01L 2224/16225; H01L 2224/32225; H01L 2224/73204

(57) ABSTRACT

A semiconductor package may include a first redistribution structure, a first semiconductor chip on the first redistribution structure, a first molding layer covering the first semiconductor chip, first connection structures on the first redistribution structure and extending in a vertical direction while passing through the first molding layer, a second redistribution structure on the first semiconductor chip, a second semiconductor chip on the second redistribution structure, and a metal layer on the second semiconductor chip. The metal layer may be in contact with an upper surface of the second semiconductor chip.

### CROSS-REFERENCE TO RELATED APPLICATION

This application is based on and claims priority under 35 U.S.C. § 119 to Korean Patent Application No. 10-2022-0112173, filed on Sep. 5, 2022 in the Korean Intellectual Property Office, the disclosure of which is incorporated by reference herein in its entirety.

### BACKGROUND

Inventive concepts relate to a semiconductor package. More particularly, inventive concepts relate to a semiconductor package including a plurality of chips.

With the development of the electronics industry and the demand of users, miniaturization and weight reduction of electronic components mounted on electronic products may be required. In order to meet such demand, a semiconductor package mounted on an electronic component may be required to process high-capacity data while having a low volume. Accordingly, a semiconductor package including a plurality of chips performing various functions has been proposed. Meanwhile, for heat generated by operations of a plurality of chips, studies have been conducted to improve the heat dissipation performance of a semiconductor package.

### SUMMARY

An aspect of inventive concepts is to provide a semiconductor package with improved thermal characteristics.

Another aspect of inventive concepts is to provide a semiconductor package with reduced manufacturing costs.

According to an embodiment of inventive concepts, a semiconductor package may include a first redistribution structure; a first semiconductor chip on the first redistribution structure; a first molding layer covering the first semiconductor chip; first connection structures on the first redistribution structure, the first connection structures extending in a vertical direction while passing through the first molding layer; a second redistribution structure on the first semiconductor chip; a second semiconductor chip on the second redistribution structure; and a metal layer on the second semiconductor chip. The metal layer may be in contact with an upper surface of the second semiconductor chip.

According to an embodiment of inventive concepts, semiconductor package may include a lower redistribution structure; a sub-semiconductor package on the lower redistribution structure; a lower molding layer covering the sub-semiconductor package; a lower connection structure on the lower redistribution structure and extending in a vertical direction while passing through the lower molding layer; and an upper redistribution structure on the sub-semiconductor package. The sub-semiconductor package may include a first redistribution structure, a first semiconductor chip on the first redistribution structure, a first molding layer surrounding the first semiconductor chip, first connection structures on the first redistribution structure, a second redistribution structure on the first semiconductor chip, a second semiconductor chip on the second redistribution structure, a second molding layer surrounding the second semiconductor chip, and a metal layer on the second semiconductor chip. The first connection structures may extend in the vertical direction while passing through the first molding layer. The metal layer may be in contact with an upper surface of the second semiconductor chip.

According to an embodiment of inventive concepts, a semiconductor package may include a first redistribution structure; a first semiconductor chip on the first redistribution structure; a first connection terminal between the first redistribution structure and the first semiconductor chip, the first connection terminal connecting the first redistribution structure and the first semiconductor chip; a first molding layer covering the first semiconductor chip; first connection structures on the first redistribution structure, the first connection structures extending in a vertical direction while passing through the first molding layer; a second redistribution structure on the first semiconductor chip; second connection structures between the first semiconductor chip and the second redistribution structure, the second connection structures electrically connecting the first semiconductor chip and the second redistribution structure to each other; a second semiconductor chip on the second redistribution structure, the second semiconductor chip having a horizontal area larger than a horizontal area of the first semiconductor chip; a second connection terminal between the second redistribution structure and the second semiconductor chip, the second connection terminal connecting the second redistribution structure and the second semiconductor chip to each other; a second molding layer covering the second semiconductor chip; and a metal layer on the second semiconductor chip. The metal layer may completely cover an upper surface of the second semiconductor chip and an upper surface of the second molding layer.

### BRIEF DESCRIPTION OF THE DRAWINGS

Embodiments will be more clearly understood from the following detailed description taken in conjunction with the accompanying drawings in which:

FIG. 1 shows a cross-sectional view of a semiconductor package according to an embodiment;

FIG. 2A shows an enlarged cross-sectional view of an EX1 region of FIG. 1;

FIG. 2B shows an enlarged cross-sectional view of an EX2 region of FIG. 1;

FIG. 3 shows a cross-sectional view of a semiconductor package according to an embodiment;

FIGS. 4A and 4B show cross-sectional views of a semiconductor package according to an embodiment;

FIG. 5 shows a cross-sectional view of a semiconductor package according to an embodiment;

FIGS. 6A to 6G show cross-sectional views of respective steps in a method of manufacturing a semiconductor package according to an embodiment;

FIGS. 7A to 7D show cross-sectional views of respective steps in a method of manufacturing a semiconductor package according to an embodiment; and

FIG. 8 shows a cross-sectional view of a method of manufacturing a semiconductor package according to an embodiment.

### DETAILED DESCRIPTION

Hereinafter, embodiments of inventive concepts will be described in detail with reference to the accompanying drawings. The same reference numerals are used for the same components in the drawings, and redundant description thereof is omitted.

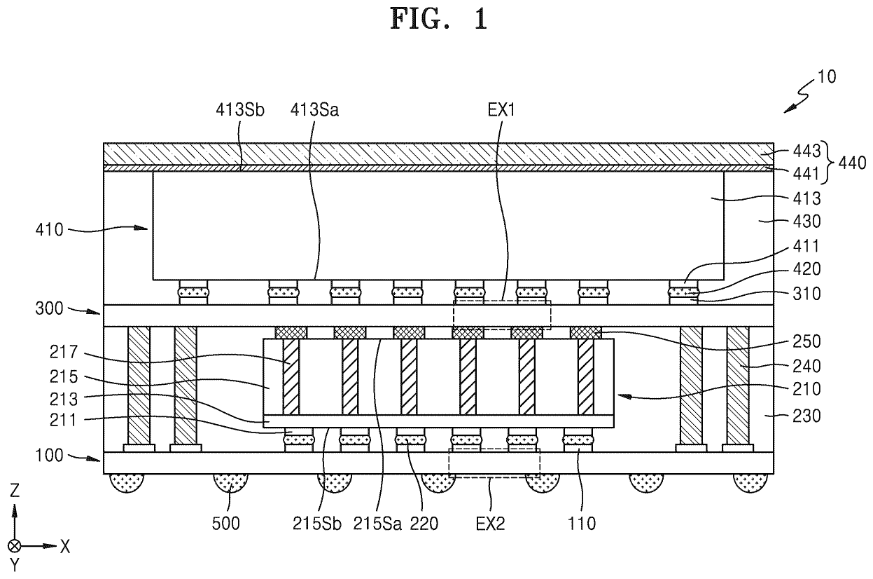

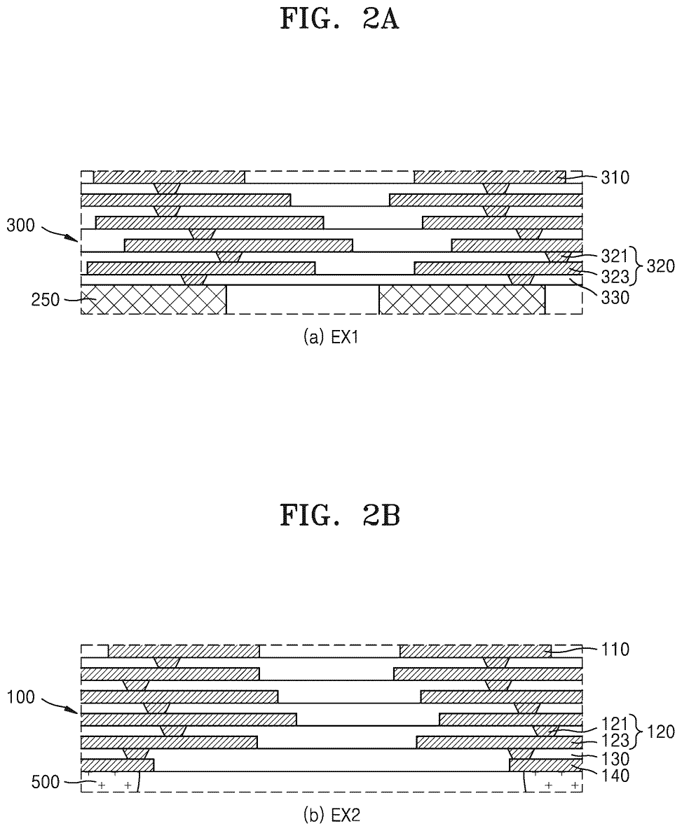

FIG. 1 shows a cross-sectional view of a semiconductor package 10 according to an embodiment. FIG. 2A is an enlarged cross-sectional view of an enlarged EX1 region of FIG. 1 and FIG. 2B is an enlarged cross-sectional view of an enlarged EX2 region of FIG. 1.

Referring to FIGS. 1. 2A. and 2B, a semiconductor package 10 may include a first redistribution structure 100, a first semiconductor chip 210, a first molding layer 230, a first connection structure 240, a second redistribution structure 300, a second semiconductor chip 410, a second molding layer 430, and a metal layer 440.

The first redistribution structure 100 may be a substrate and the first semiconductor chip 210 may be mounted on the first redistribution structure 100. Referring to FIGS. 1 and 2B together, the first redistribution structure 100 may include a first redistribution pattern 120 and a first redistribution insulating layer 130. Hereinafter, unless otherwise specified, a direction parallel to the upper surface of the first redistribution structure 100 is defined as a horizontal direction (that is, X direction and Y direction), and a direction perpendicular to the upper surface of the first redistribution structure 100 as a vertical direction (that is, Z direction).

The first redistribution insulating layer 130 may cover the first redistribution pattern 120. The first redistribution insulating layer 130 may include (or be composed of) a plurality of insulating layers stacked in the vertical direction, or may include (or be composed of) a single insulating layer. The first redistribution insulating layer 130 may include, for example, a photo imageable dielectric (PID), or a photosensitive polyimide (PSPI).

The first redistribution pattern 120 may include a plurality of first redistribution lines 123 extending in the horizontal direction and a plurality of first redistribution vias 121 extending while at least partially passing through the first redistribution insulating layer 130. The plurality of first redistribution lines 123 may extend in the horizontal direction along at least one surface among the upper surface and the lower surface of each of insulating layers that constitute the first redistribution insulating layer 130. A portion of the plurality of first redistribution lines 123 may be located at a vertical level different from the remaining portion of the plurality of the first redistribution lines 123. The plurality of first redistribution vias 121 may electrically connect the plurality of first redistribution lines 123 located at different vertical levels. In an embodiment, the horizontal width of the plurality of first redistribution vias 121 may become larger as adjacent to the first semiconductor chip 210. The first redistribution pattern 120 may include, for example, a metal selected from copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or an alloy thereof. The first redistribution pattern 120 may include a plurality of first redistribution pads 110 at the top end thereof. The lower surface of the plurality of first redistribution pads 110 may be covered by the first redistribution insulating layer 130.

A plurality of UBM layers 140 may be disposed at the bottom end of the first redistribution pattern 120. At least a portion of each of the plurality of UBM layers 140 may be covered by the first redistribution insulating layer 130. For example, the upper surface and sidewalls of each of the plurality of UBM layers 140 may be completely covered by the first redistribution insulating layer 130. The plurality of UBM layers 140 may electrically connect the first redistribution pattern 120 to an external connection terminal 500. The plurality of UBM layers 140 may include, for example, a metal selected from copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or an alloy thereof. The plurality of UBM layers 140 may further include a UBM seed layer (not shown). In this case, the UBM seed layer may be formed, for example, by performing a physical vapor deposition process, and the plurality of UBM layers 140 may be formed via an electroplating process using the UBM seed layer.

Referring again to FIG. 1, an external connection terminal 500 may be disposed on the lower surface of the first redistribution structure 100. A portion of the external connection terminal 500 may be disposed so as not to overlap the first semiconductor chip 210 and the second semiconductor chip 410 in the vertical direction. The external connection terminal 500 may include solder, for example. The external connection terminal 500 may physically and electrically connect an external instrument to the semiconductor package 10.

The first semiconductor chip 210 may be mounted on the first redistribution structure 100. In an embodiment, the first semiconductor chip 210 may be a memory chip or a logic chip. The memory chip may be, for example, a volatile memory chip selected from a dynamic random access memory (DRAM) or a static random access memory (SRAM), or may be a non-volatile memory chip selected from a phase-change random access memory (PRAM), a magnetoresistive random access memory (MRAM), a ferroelectric random access network (FeRAM), or a resistive random access memory (RRAM). In addition, the logic chip may be, for example, a microprocessor, an analog device, or a digital signal processor. The first semiconductor chip 210 may include a first chip pad 211, a distribution structure 213, a first semiconductor substrate 215, and a through electrode 217.

The first semiconductor substrate 215 may include a Group IV semiconductor selected from silicon (Si) or germanium (Ge), a Group IV-IV compound semiconductor selected from silicon-germanium (SiGe) or silicon carbide (SiC), or a Group III-V compound semiconductor selected from gallium arsenide (GaAs), indium arsenide (InAs), or indium phosphide (InP). The first semiconductor substrate 215 may include a conductive region, for example, a well doped with impurities. The first semiconductor substrate 215 may have various device isolation structures including a shallow trench isolation (STI) structure.

The first semiconductor substrate 215 may have a first active surface 215Sa and a first inactive surface 215Sb opposite the first active surface 215Sa. The first active surface 215Sa of the first semiconductor substrate 215 may correspond to the upper surface of the first semiconductor substrate 215 facing the second redistribution structure 300, and the first inactive surface 215Sb of the first semiconductor substrate 215 may correspond to the lower surface of the first semiconductor substrate 215 facing the first redistribution structure 100.

On the first active surface 215Sa, a first FEOL structure (not shown) and a first BEOL structure may be disposed. For example, the first FEOL structure may be disposed on the first active surface 215Sa, and the first BEOL structure may be disposed on the first FEOL structure.

The first FEOL structure may include a plurality of first individual devices of various kinds. The plurality of individual devices may include various micro electronic devices, for example, metal-oxide-semiconductor field effect transistors (MOSFETs) selected from complementary metal-oxide semiconductor transistors (CMOS transistors) or the like, image sensors selected from system large scale integration (LSI), CMOS imaging sensors (CIS), or the like, micro-electro-mechanical systems (MEMSs), active devices, passive devices, or the like. The plurality of first individual devices may be electrically connected to a conductive region of the first semiconductor substrate 215. Each of the plurality of first individual devices may be electrically isolated from other neighboring individual devices by a first insulating layer (not shown).

The first BEOL structure may include a first BEOL insulating layer (not shown) and a first BEOL pattern (not shown) covered by the first BEOL insulating layer. The first BEOL pattern may be electrically connected to the plurality of first individual devices and a conductive region of the first semiconductor substrate 215. The first BEOL pattern may include, for example, a metal selected from copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or an alloy thereof.

The distribution structure 213 may be disposed on the lower surface of the first semiconductor substrate 215. The distribution structure 213 may include a distribution insulating layer (not shown) and a distribution pattern (not shown) covered with the distribution insulating layer. The first chip pad 211 may be disposed on the lower surface of the distribution structure 213.

The through electrode 217 may extend in the vertical direction while passing through the first semiconductor substrate 215. The through electrode 217 may electrically connect the distribution structure 213 to the first BEOL structure disposed on the first active surface 215Sa. The through electrode 217 may include a pillar-shaped conductive plug and a conductive barrier layer surrounding a sidewall of the conductive plug. The conductive plug may include, for example, at least one material selected from copper (Cu), nickel (Ni), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru). The conductive barrier layer may include at least one material selected from titanium (Ti), titanium nitride (TiN), tantalum (Ta), tantalum nitride (TaN), tungsten (W), tungsten nitride (WN), ruthenium (Ru), and cobalt (Co). The through electrode 217 is shown in FIG. 1 as being included in the first semiconductor chip 210, but is not limited thereto. For example, the first semiconductor chip 210 may not include a through electrode, and the second semiconductor chip 410 may include a through electrode, unlike shown in FIG. 1.

A first connection terminal 220 may be arranged between the first semiconductor chip 210 and the first redistribution structure 100. The first connection terminal 220 may be in contact with the first chip pad 211 of the first semiconductor chip 210 and the first redistribution pads 110 of the first redistribution structure 100, and may physically and electrically connect the first semiconductor chip 210 and the first redistribution structure 100. The first connection terminal 220 may include, for example, at least one among solder, tin (Sn), silver (Ag), copper (Cu), and aluminum (Al).

The first molding layer 230 may be disposed on the first redistribution structure 100 and cover at least a portion of the first semiconductor chip 210. Specifically, the first molding layer 230 may extend along the upper surface, lower surface, and opposite sidewalls of the first semiconductor chip 210 and cover the upper surface, lower surface, and opposite sidewalls of the first semiconductor chip 210. In an embodiment, the first molding layer 230 may include an insulating polymer or an epoxy resin. For example, the first molding layer 230 may include an epoxy molding compound (EMC).

The first connection structure 240 may be disposed on the first redistribution structure 100 and connected to the first redistribution pads 110 of the first redistribution structure 100. The first connection structure 240 may extend in the vertical direction while passing through the first molding layer 230. The first redistribution structure 100 may be electrically connected to the second redistribution structure 300 by the first connection structure 240.

The second connection structure 250 may be disposed on the first semiconductor chip 210 and connected to the through electrode 217 of the first semiconductor chip 210. In the case where the first FEOL structure and the first BEOL structure are disposed on the first active surface 215Sa of the first semiconductor substrate 215, the second connection structure 250 may be connected to the first BEOL structure. The second connection structure 250 may extend in the vertical direction while passing through a portion of the first molding layer 230. The upper surface of the second connection structure 250, the upper surface of the first connection structure 240, and the upper surface of the first molding layer 230 may be coplanar. By the second connection structure 250, the first semiconductor chip 210 may be electrically connected to the second redistribution structure 300. In an embodiment, the second connection structure 250 may be a conductive pillar including Cu. However, without being limited thereto, the second connection structure 250 may be a conductive bump or conductive solder.

The second redistribution structure 300 may be disposed on the first molding layer 230. The second redistribution structure 300 may be a substrate to which the second semiconductor chip 410 is mounted. Referring to FIGS. 1 and 2A together, the second redistribution structure 300 may include a second redistribution pattern 320 and a second redistribution insulating layer 330.

The second redistribution insulating layer 330 may cover the second redistribution pattern 320. The second redistribution insulating layer 330 may include (or be composed of) a plurality of insulating layers stacked in the vertical direction, or may include (or be composed of) a single insulating layer. The second redistribution insulating layer 330 may include, for example, a photo imageable dielectric (PID), or a photosensitive polyimide (PSPI).

The second redistribution pattern 320 may include a plurality of second redistribution lines 323 extending in the horizontal direction and a plurality second redistribution vias 321 extending while at least partially passing through the second redistribution insulating layer 330. The plurality of second redistribution lines 323 may extend in the horizontal direction along at least one surface among the upper surface and the lower surface of each of insulating layers that constitute the second redistribution insulating layer 330. A portion of the plurality of second redistribution lines 323 may be located at a vertical level different from the remaining portion of the plurality of the second redistribution lines 323. The plurality of second redistribution vias 321 may electrically connect the plurality of second redistribution lines 323 located at different vertical levels. In an embodiment, the horizontal width of the plurality of second redistribution vias 321 may become smaller as adjacent to the first semiconductor chip 210. The second redistribution pattern 320 may include, for example, a metal selected from copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or an alloy thereof. The second redistribution pattern 320 may include a plurality of second redistribution pads 310 at the top end thereof. The lower surface of the plurality of second redistribution pads 310 may be covered by the second redistribution insulating layer 330.

Referring again to FIG. 1, the second semiconductor chip 410 may be mounted on the second redistribution structure 300. The second semiconductor chip 410 may include a second chip pad 411 and a second semiconductor substrate 413.

In an embodiment, the second semiconductor chip 410 may be a memory chip or a logic chip. In an embodiment, the first semiconductor chip 210 and the second semiconductor chip 410 may be semiconductor chips of the same kind or may be semiconductor chips of different kinds.

In an embodiment, the first semiconductor chip 210 and the second semiconductor chip 410 may be logic chips. In an embodiment, the first semiconductor chip 210 may be electrically connected to the second semiconductor chip 410 to operate as one logic chip therewith. For example, the first semiconductor chip 210 may be a PHY chip or a Modem chip, the second semiconductor chip 410 may be a CPU chip or a GPU chip, and the first semiconductor chip 210 and the second semiconductor chip 410 may operate as one logic chip.

The second semiconductor chip 410 may be mounted on the second redistribution structure 300 so as to overlap the first semiconductor chip 210 in the vertical direction. At this time, the center of the second semiconductor chip 410 may overlap the center of the frist semiconductor chip 210 in the vertical direction.

In an embodiment, the horizontal area of the second semiconductor chip 410 may be larger than the horizontal area of the first semiconductor chip 210. Here, the horizontal area means an area on a plane perpendicular to the vertical direction (that is, an area in an X-Y plane).

The second semiconductor substrate 413 may include a material that is the same as or similar to that of the first semiconductor substrate 215. The second semiconductor substrate 413 may include a conductive region, for example, a well doped with impurities, or a structure doped with impurities. In addition, the second semiconductor substrate 413 may have various device isolation structures including an STI structure.

The second semiconductor substrate 413 may have a second active surface 413Sa and a second inactive surface 413Sb opposite the second active surface 413Sa. The second active surface 413Sa of the second semiconductor substrate 413 may correspond to the lower surface of the second semiconductor substrate 413 facing the second redistribution structure 300, and the second inactive surface 413Sb of the second semiconductor substrate 413 may correspond to the upper surface of the second semiconductor substrate 413 facing the metal layer 440.

On the second active surface 413Sa, a second FEOL structure (not shown) and a second BEOL structure (not shown) may be disposed. For example, the second FEOL structure may be disposed on the second active surface 413Sa, and the second BEOL structure may be disposed on the second FEOL structure.

The second FEOL structure may include a plurality of second individual devices of various kinds. The plurality of second individual devices may include various microelectronic devices, for example, MOSFETs selected from CMOS transistors or the like, image sensors selected from system LSI, CISs, or the like, MEMSs, active devices, passive devices, or the like. The plurality of second individual devices may be electrically connected to a conductive region of the second semiconductor substrate 413. Each of the plurality of second individual devices may be electrically isolated from other neighboring individual devices by a second insulating layer (not shown).

The second BEOL structure may include a second BEOL insulating layer (not shown) and a second BEOL pattern (not shown) covered by the second BEOL insulating layer. The second BEOL pattern may be electrically connected to the plurality of second individual devices and a conductive region of the second semiconductor substrate 413. The second BEOL pattern may include a material that is the same as or similar to that of the first BEOL pattern.

A second connection terminal 420 may be arranged between the second semiconductor chip 410 and the second redistribution structure 300. The second connection terminal 420 may be in contact with the second chip pad 411 of the second semiconductor chip 410 and the second redistribution pads 310 of second redistribution structure 300, and may physically and electrically connect the second semiconductor chip 410 to the second redistribution structure 300. The second connection terminal 420 may include a material that is substantially the same as or similar to that of the first connection terminal 220.

The second molding layer 430 may be disposed on the second redistribution structure 300 and cover at least a portion of the second semiconductor chip 410. Specifically, the second molding layer 430 may extend along the lower surface and opposite sidewalls of the second semiconductor chip 410 and cover the lower surface and opposite sidewalls of the second semiconductor chip 410. At this time, the upper surface of the second molding layer 430 and the upper surface of the second semiconductor chip 410 may be coplanar. In an embodiment, the second molding layer 430 may include an insulating polymer or an epoxy resin. In an embodiment, the second molding layer 430 and the first molding layer 230 may be made of different materials.

The metal layer 440 may be disposed on the second semiconductor chip 410 and the second molding layer 430. In an embodiment, the metal layer 440 may completely cover the upper surface of the second semiconductor chip 410 and the upper surface of the second molding layer 430. In an embodiment, the metal layer 440 may include a first metal layer 441 in contact with the upper surface of the second semiconductor chip 410 and the upper surface of the second molding layer, and a second metal layer 443 disposed on the first metal layer 441. In an embodiment, the first metal layer 441 may include Ti, and the second metal layer 443 may include Cu.

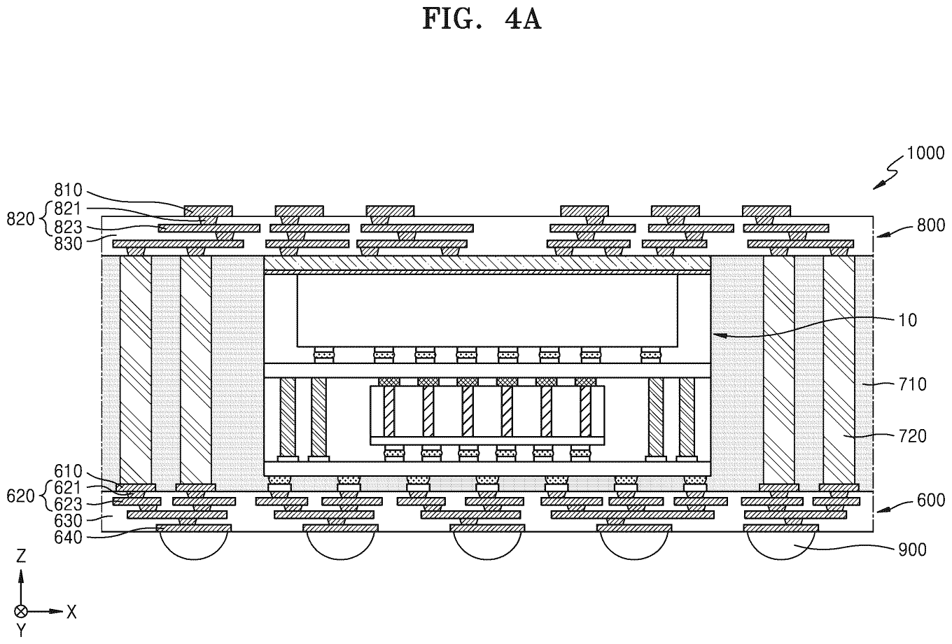

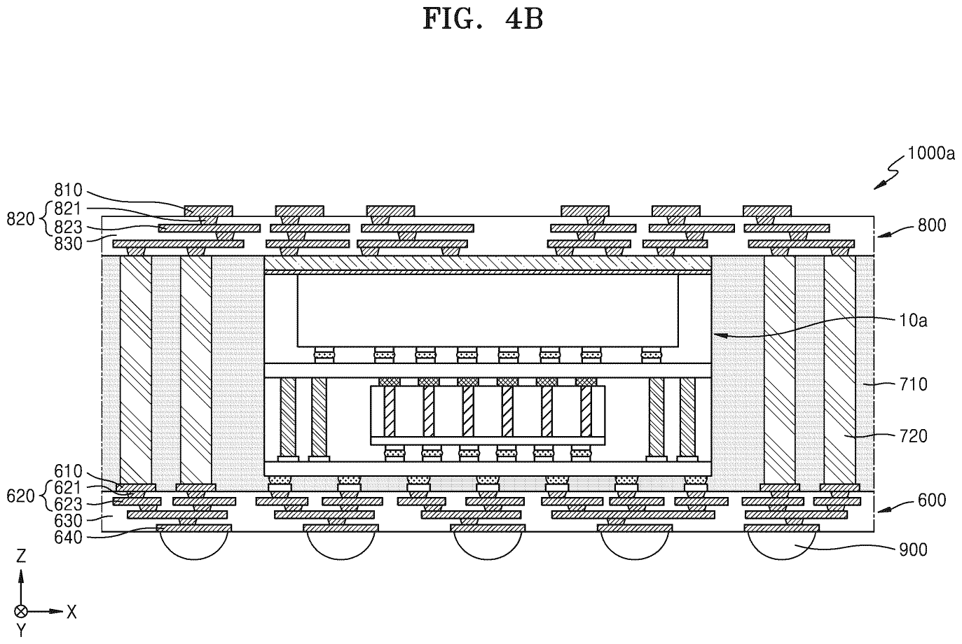

The metal layer 440 which may be included in the semiconductor package 10 according to an embodiment may be disposed on the second semiconductor chip 410 and in contact with the upper surface of the second semiconductor chip 410. Accordingly, heat generated as the second semiconductor chip 410 performs an arithmetic operation may be easily released through the metal layer 440, and thus the thermal characteristics of the semiconductor package 10 may be improved. In addition, since the metal layer 440 is disposed to cover the upper surface of the second molding layer 430, the second molding layer 430 may be limited and/or prevented from being exposed to the outside in a procedure of forming and planarizing a first molding layer 710 (see FIG. 4A, FIG. 4B) covering the semiconductor package 10. Accordingly, generation of a void due to exposure of the second molding layer 430 may be limited and/or prevented.

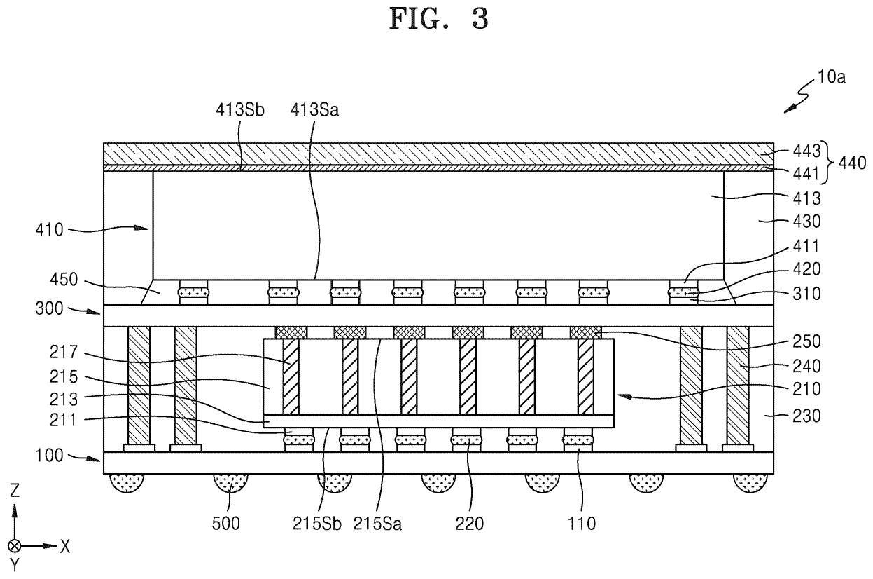

FIG. 3 shows a cross-sectional view of a semiconductor package 10a according to an embodiment. Since the respective configurations of the semiconductor package 10a shown in FIG. 3 are similar to the respective corresponding configurations of the semiconductor package 10 shown in FIG. 1, the following description focuses on differences.

Referring to FIG. 3, the semiconductor package 10a may further include an underfill layer 450 arranged between the second semiconductor chip 410 and the second redistribution structure 300. The underfill layer 450 may cover the second chip pad 411, the second redistribution pads 310, and the second connection terminal 420 and fill a space between the second semiconductor chip 410 and the second redistribution structure 300. The underfill layer 450 may include an insulating resin. In an embodiment, the underfill layer 450 may be a portion of the second molding layer 430 formed in a molded under-fill (MUF) manner.

FIGS. 4A and 4B show cross-sectional views of a semiconductor package 1000 or 1000a according to an embodiment.

Referring to FIG. 4A, the semiconductor package 1000 may include a lower redistribution structure 600, the semiconductor package 10, a lower molding layer 710, lower connection structures 720, and an upper redistribution structure 800. The semiconductor package 10 may be referred to as a sub-semiconductor package of the semiconductor package 1000.

The lower redistribution structure 600 may be a substrate to which the semiconductor package 10 is mounted. The lower redistribution structure 600 may include a lower redistribution pattern 620 and a lower redistribution insulating layer 630.

The lower redistribution insulating layer 630 may cover the lower redistribution pattern 620. The lower redistribution insulating layer 630 may include (or be composed of) a plurality of insulating layers stacked in the vertical direction, or may include (or be composed of) a single insulating layer. The lower redistribution insulating layer 630 may include, for example, a photo imageable dielectric (PID), or a photosensitive polyimide (PSPI).

The lower redistribution pattern 620 may include a plurality of lower redistribution lines 623 extending in the horizontal direction and a plurality of lower redistribution vias 621 extending while at least partially passing through the lower redistribution insulating layer 630. The plurality of lower redistribution lines 623 may extend in the horizontal direction along at least one surface among the upper surface and the lower surface of each of insulating layers that constitute the lower redistribution insulating layer 630. A portion of the plurality of lower redistribution lines 623 may be located at a vertical level different from the remaining portion of the plurality of lower redistribution lines 623. The plurality of lower redistribution vias 621 may electrically connect a plurality of lower redistribution lines 623 located at different vertical levels. In an embodiment, the horizontal width of the plurality of lower redistribution vias 621 may become larger as adjacent to the semiconductor package 10. The lower redistribution pattern 620 may include, for example, a metal selected from copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or an alloy thereof. The lower redistribution pattern 620 may include a plurality of lower redistribution pads 610 at the top end thereof. The lower surface of the plurality of lower redistribution pads 610 may be covered by the lower redistribution insulating layer 630.

A plurality of lower UBM layers 640 may be disposed at the bottom end of the lower redistribution pattern 620. At least a portion of each of the plurality of lower UBM layers 640 may be covered by the lower redistribution insulating layer 630. For example, the lower surface and sidewalls of each of the plurality of lower UBM layers 640 may be completely covered by the lower redistribution insulating layer 630. The plurality of lower UBM layers 640 may electrically connect the lower redistribution pattern 620 to an external connection terminal 900.

An external connection terminal 900 may be disposed on the lower surface of the lower redistribution structure 600. A portion of the external connection terminal 900 may be disposed so as not to overlap the semiconductor package 10 in the vertical direction. The external connection terminal 900 may include solder, for example. The external connection terminal 900 may physically and electrically connect an external instrument to the semiconductor package 1000.

The semiconductor package 10 may be mounted on the lower redistribution structure 600. Since the semiconductor package 10 has been described with reference to FIG. 1, a detailed description of the semiconductor package 10 is omitted.

The lower molding layer 710 is disposed on the lower redistribution structure 600 and may cover at least a portion of the semiconductor package 10. Specifically, the lower molding layer 710 may extend along the lower surface and opposite sidewalls of the semiconductor package 10 and cover the lower surface and opposite sidewalls of the semiconductor package 10. The upper surface of the lower molding layer 710 and the upper surface of the semiconductor package 10 may be coplanar. Specifically, the upper surface of the lower molding layer 710 and the upper surface of the metal layer 440 (see FIG. 1) of the semiconductor package 10 may be coplanar. The lower molding layer 710 may include an insulating polymer or an epoxy resin. For example, the lower molding layer 710 may include an epoxy molding compound (EMC). In an embodiment, the lower molding layer 710 may be made of a material different from that of at least one selected from the first molding layer 130 (see FIG. 1) or the second molding layer 430 (see FIG. 1) of the semiconductor package 10. For example, the lower molding layer 710 may be made of a material that is the same as that of the first molding layer 230 and may be made of a material different from that of the second molding layer 430.

The lower connection structures 720 may be disposed on the lower redistribution structure 600 and connected to the lower redistribution pads 610 of the lower redistribution structure 600. The lower connection structures 720 may extend in the vertical direction while passing through the lower molding layer 710.

The upper redistribution structure 800 may be disposed on the lower molding layer 710. The upper redistribution structure 800 may include an upper redistribution pattern 820 and an upper redistribution insulating layer 830.

The upper redistribution insulating layer 830 may cover the upper redistribution pattern 820. The upper redistribution insulating layer 830 may include (or be composed of) a plurality of insulating layers stacked in the vertical direction, or may include (or be composed of) a single insulating layer. The upper redistribution insulating layer 830 may include, for example, a photo imageable dielectric (PID), or a photosensitive polyimide (PSPI).

The upper redistribution pattern 820 may include a plurality of upper redistribution lines 823 extending in the horizontal direction and a plurality upper redistribution vias 821 extending while at least partially passing through the upper redistribution insulating layer 830. The plurality of upper redistribution lines 823 may extend in the horizontal direction along at least one surface among the upper surface and the lower surface of each of insulating layers that constitute the upper redistribution insulating layer 830. A portion of the plurality of upper redistribution lines 823 may be located at a vertical level different from the remaining portion of the plurality of the upper redistribution lines 823. The plurality of upper redistribution vias 821 may electrically connect the plurality of upper redistribution lines 823 located at different vertical levels. In an embodiment, the horizontal width of the plurality of upper redistribution vias 821 may become smaller as adjacent to the semiconductor package 10.

In an embodiment, a portion that overlaps the semiconductor package 10 in the vertical direction among the plurality of upper redistribution vias 821 may be in contact with the metal layer 440 of the semiconductor packaging 10.

In an embodiment, the remaining portion that does not overlap the semiconductor package 10 in the vertical direction among the plurality of upper redistribution vias 821 may be in contact with the lower connection structures 720. Accordingly, through the lower connection structures 720, the upper redistribution structure 800 may be electrically connected to the lower redistribution structure 600.

The upper redistribution pattern 820 may include, for example, a metal selected from copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or an alloy thereof. The upper redistribution pattern 820 may include a plurality of upper redistribution pads 810 at the top end thereof. The lower surface of the plurality of upper redistribution patterns 820 may be covered by the upper redistribution insulating layer 830.

Referring to FIG. 4B, the semiconductor package 1000a may include the lower redistribution structure 600, the semiconductor package 10a, the lower molding layer 710, the lower connection structures 720, and the upper redistribution structure 800. Since the respective configurations of the semiconductor package 1000a shown in FIG. 4B are similar to the corresponding respective configurations of the semiconductor package 1000 shown in FIG. 4A and the semiconductor package 10a has been described with reference to FIG. 3, a description of the semiconductor package 1000a is omitted. The semiconductor package 10a may be referred to as a sub-semiconductor package of the semiconductor package 1000a.

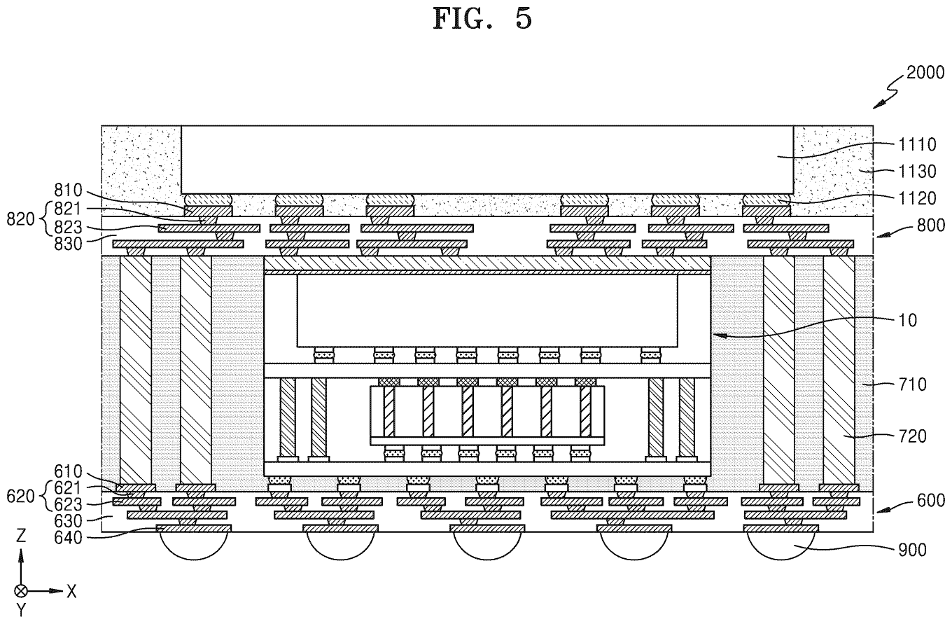

FIG. 5 shows a cross-sectional view of a semiconductor package 2000 according to an embodiment.

Referring to FIG. 5, the semiconductor package 2000 may include the lower redistribution structure 600, the semiconductor package 10, the lower molding layer 710, the lower connection structures 720, the upper redistribution structure 800, an upper semiconductor chip 1110, and an upper molding layer 1130. The lower redistribution structure 600, the semiconductor package 10, the lower molding layer 710, the lower connection structures 720, and the upper redistribution structure 800 are similar to the corresponding respective configurations of the semiconductor package 1000 described with reference to FIG. 4A, the following description focuses on differences. In addition, the semiconductor package 2000 is shown in FIG. 5 as including the semiconductor package 10 described with reference to FIG. 1, but is not limited thereto, and it is also possible to include the semiconductor package 10a described with reference to FIG. 3.

The upper semiconductor chip 1110 may be disposed on the upper redistribution structure 800. In an embodiment, the upper semiconductor chip 1110 may be a memory chip or a logic chip. In an embodiment, the first semiconductor chip 210 (see FIG. 1) and the second semiconductor chip 410 (see FIG. 1) may be logic chips and the upper semiconductor chip 1110 may be a memory chip. For example, the first semiconductor chip 210 and the second semiconductor chip 410 may be CPU chips and the upper semiconductor chip 1110 may be a DRAM chip. The semiconductor package 2000 is shown in FIG. 5 as including one upper semiconductor chip 1110, but is not limited thereto, and it is also possible to include a plurality of upper semiconductor chips 1110.

An upper connection terminal 1120 may be arranged between the upper semiconductor chip 1110 and the upper redistribution structure 800. The upper connection terminal 1120 may physically and electrically connect the upper semiconductor chip 1110 to the upper redistribution structure 800.

The upper molding layer 1130 may cover at least a portion of the upper semiconductor chip 1110. Specifically, the upper molding layer 1130 may extend along the lower surface and opposite sidewalls of the upper semiconductor chip 1110 and cover the lower surface and opposite sidewalls of the upper semiconductor chip 1110. The upper surface of the upper molding layer 1130 and the upper surface of the upper semiconductor chip 1110 may be coplanar. However, without being limited thereto, the upper molding layer 1130 may cover the upper surface of the upper semiconductor chip 1110, unlike shown in FIG. 5. In an embodiment, the upper molding layer 1130 may be made of a material different from that of at least one selected from the lower molding layer 710, the first molding layer 230, and the second molding layer 430. For example, the upper molding layer 1130 may be made of a material different from that of the second molding layer 430 and may be a material that is the same as those of the first molding layer 230 and the lower molding layer 710.

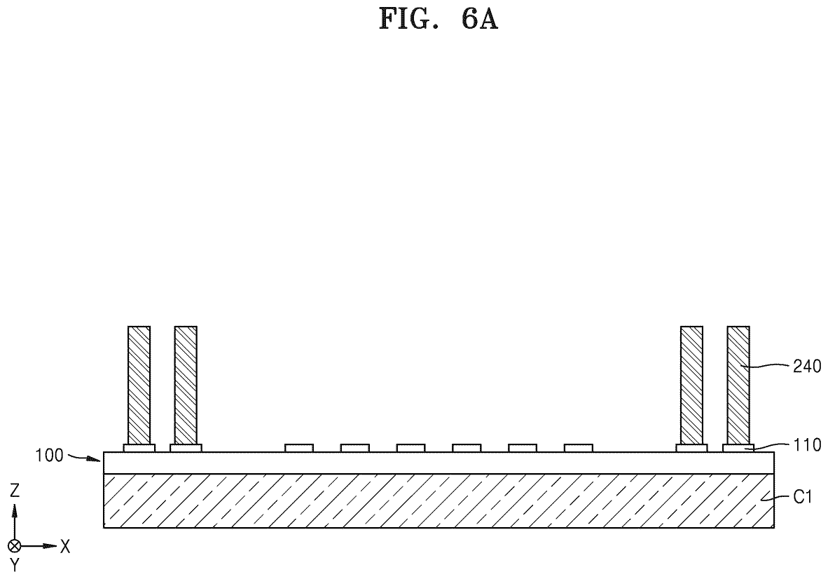

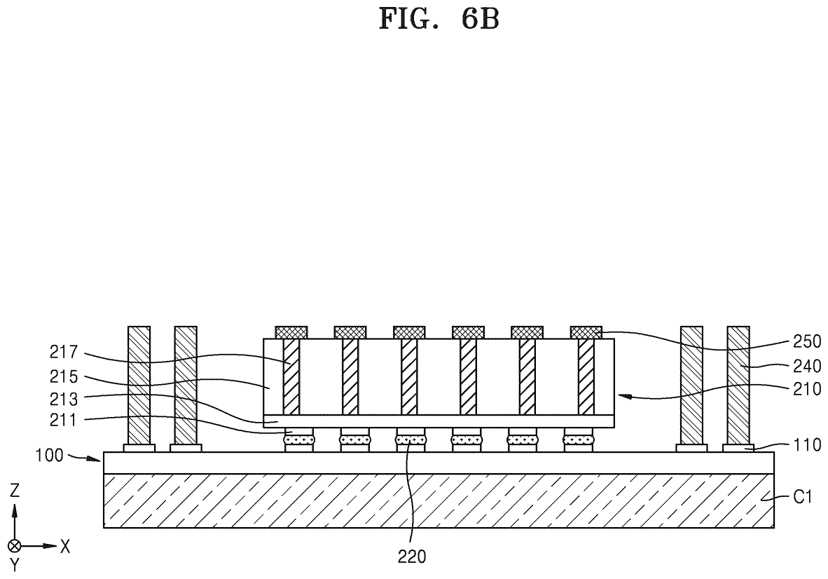

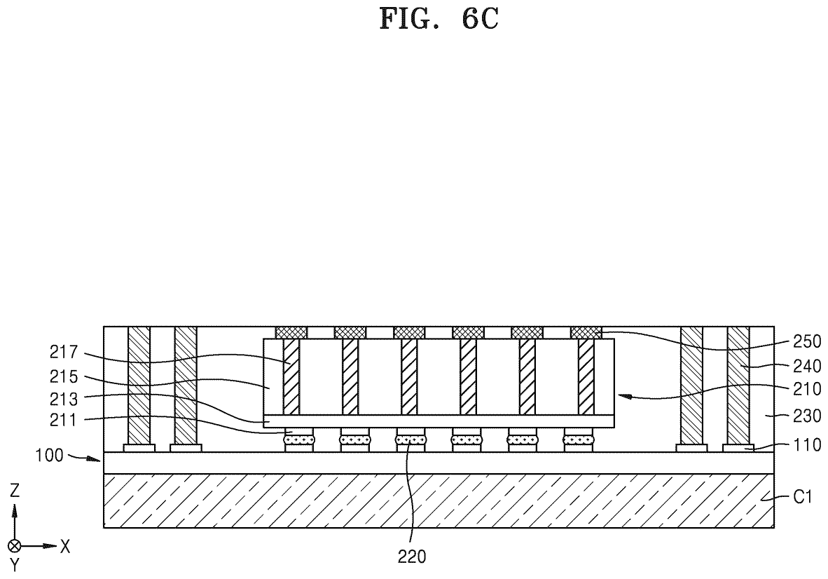

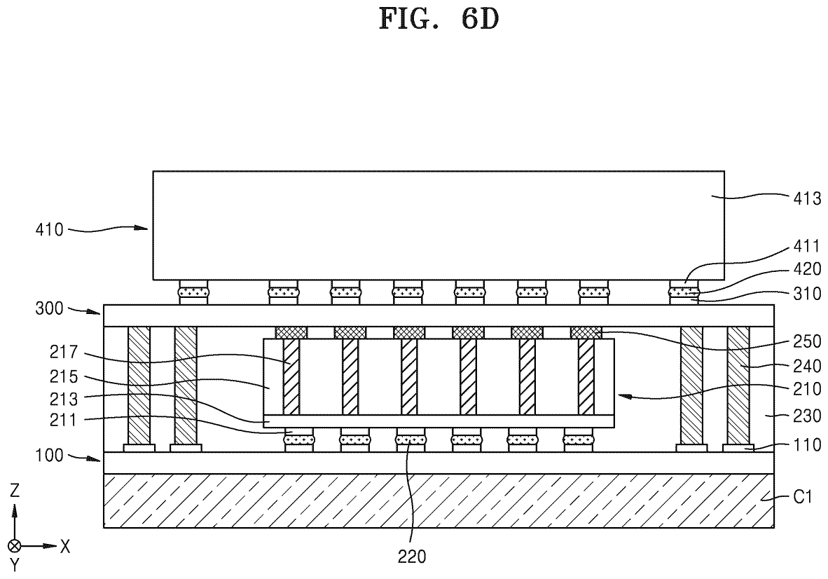

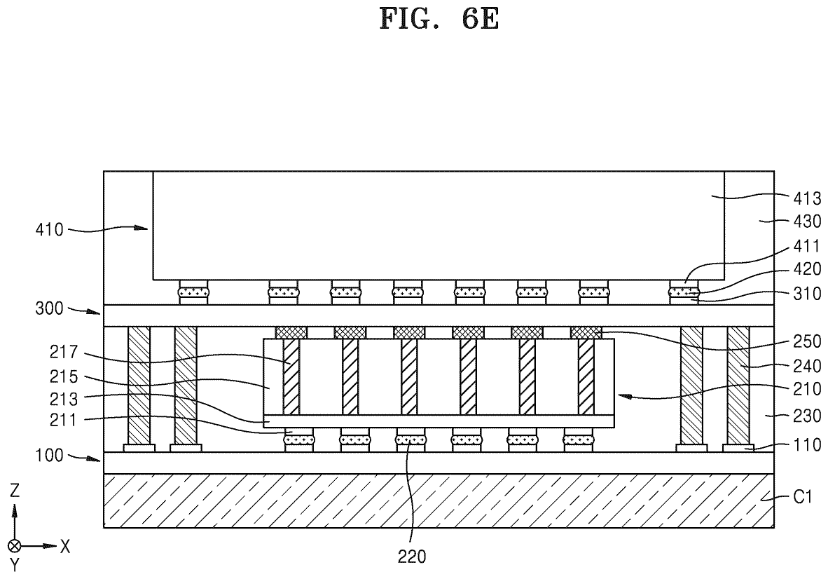

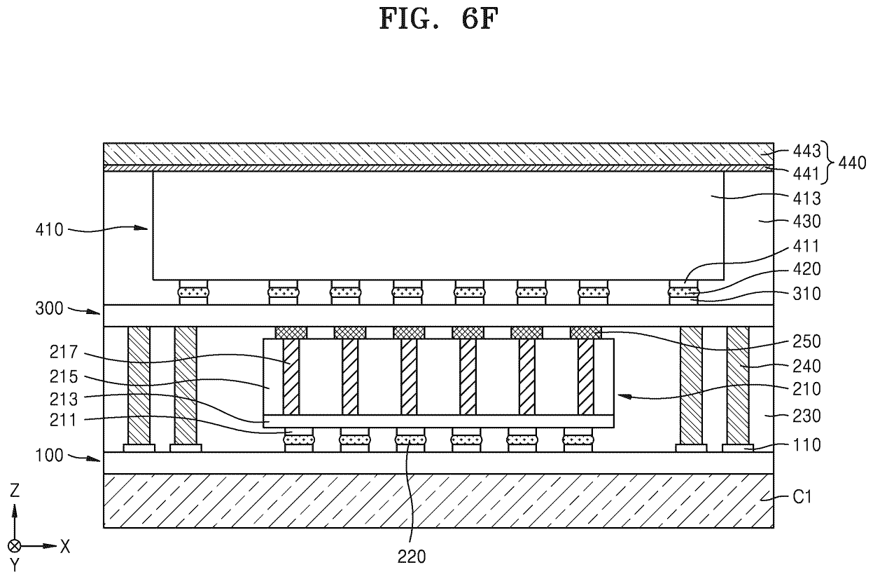

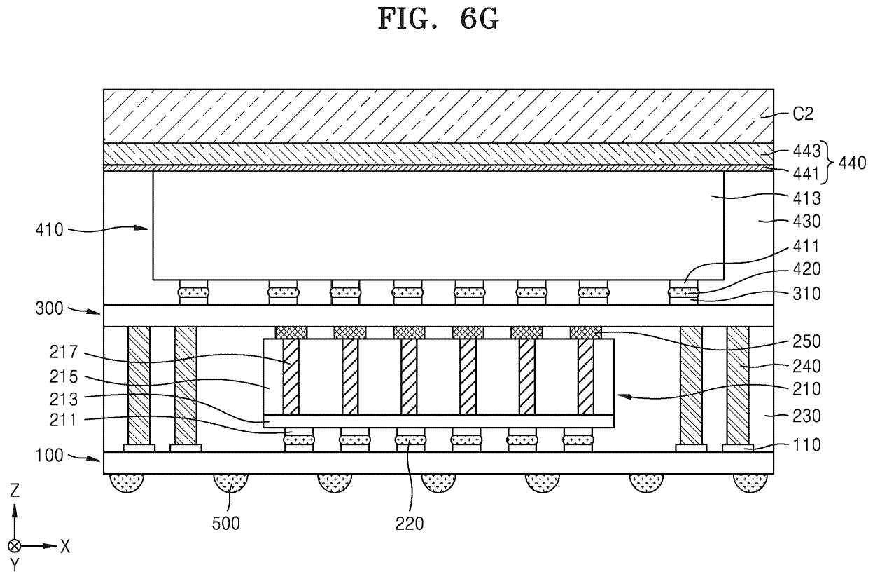

FIGS. 6A to 6G show cross-sectional views of respective steps in a method of manufacturing a semiconductor package 10 according to an embodiment.

Referring to FIG. 6A, firstly a first carrier substrate C1 may be provided. For example, the first carrier substrate C1 may be, but not limited to, a semiconductor substrate, a glass substrate, a ceramic substrate, or a plastic substrate. After the first carrier substrate C1 is provided, a first redistribution structure 100 may be formed on the first carrier substrate C1. At this time, the first redistribution insulating layer 130 (see FIG. 2B) may be formed through a lamination process, and the first redistribution pattern 120 (see FIG. 2B) may be formed through a plating process. For example, in a step of forming the first redistribution structure 100, a procedure of forming the first redistribution lines 123, forming the first redistribution insulating layer 130 covering the first redistribution lines, forming a via hole at the first redistribution insulating layer 130, and forming the first redistribution vias 121 filling the via hole may be repeated. After the first redistribution structure 100 is formed, the first connection structure 240 may be formed on the first redistribution structure 100. The first connection structure 240 may be formed, for example, by forming a seed layer and performing an electroplating process using the seed layer.

Referring to FIG. 6B, in the result of FIG. 6A, the first semiconductor chip 210 having the distribution structure 213 and the through electrode 217 and having an upper surface on which the second connection structure 250 is disposed may be mounted on the first redistribution structure 100. The first semiconductor chip 210 may be mounted on the first redistribution structure 100 through the first connection terminal 220. As the first connection terminal 220 is coupled to the first redistribution pads 110 and the first chip pad 211, the first semiconductor chip 210 may be fixed on the first redistribution structure 100. At this time, the first semiconductor chip 210 may be mounted such that the first inactive surface 215Sb of the first semiconductor chip 210 faces the first redistribution structure 100.

Referring to FIG. 6C, in the result of FIG. 6B, the first molding layer 230 may be formed on the first redistribution structure 100. At this time, the first molding layer 230 may cover the upper surface, lower surface, and opposite sidewalls of the first semiconductor chip 210. After the first molding layer 230 is formed, a planarization process may be performed on the first molding layer 230. As the planarization process is performed, the upper surface of the first molding layer 230 may become coplanar with the upper surface of first connection structure 240 and the upper surface of the second connection structure 250.

Referring to FIG. 6D, a second redistribution structure 300 may be formed on the first molding layer 230 on which the planarization process has been performed. The second redistribution structure 300 may be formed in the same manner as the formation of the first redistribution structure 100 described with reference to FIG. 6A. After the second redistribution structure 300 is formed, the second semiconductor chip 410 may be mounted on the second redistribution structure 300. The second semiconductor chip 410 may be mounted to the second redistribution structure 300 through the second connection terminal 420. As the second connection terminal 420 is coupled to the second redistribution pads 310 and the second chip pad 411, the second semiconductor chip 410 may be fixed on the second redistribution structure 300. At this time, the second semiconductor chip 410 may be mounted such that the second active surface 413Sa of the second semiconductor chip 410 faces the second redistribution structure 300.

Referring to FIG. 6E, in the result of FIG. 6D, the second molding layer 430 may be formed on the second redistribution structure 300. At this time, the second molding layer 430 may cover the lower surface and opposite sidewalls of the second semiconductor chip 210. After the second molding layer 430 is formed, a planarization process may be performed on the second molding layer 430. As the planarization process is performed, the upper surface of the second molding layer 430 may become coplanar with the upper surface of the second semiconductor chip 410. Since the second molding layer 430 is formed via a process different from that for the first molding layer 230, the first molding layer 230 and the second molding layer 430 may be made of different materials. In an embodiment, when manufacturing the semiconductor package 10a described with reference to FIG. 3, the underfill layer 450 (see FIG. 3) may be formed firstly to fill a gap between the second semiconductor chip 410 and the second redistribution structure 300 prior to forming the second molding layer 430.

Referring to FIG. 6F, in the result of FIG. 6E, the metal layer 440 may be formed on the second semiconductor chip 410 and the second molding layer 430. Specifically, after the first metal layer 441 is formed on the second semiconductor chip 410 and the second molding layer 430, the second metal layer 443 may be formed on the first metallic layer 441. The first metal layer 441 may be formed by a deposition process, for example, physical vapor deposition (PVD). The second metal layer 443 may be formed by forming a seed layer on the first metal layer 441 via a deposition process and performing an electroplating process using the seed layer. In an embodiment, the first metal layer 441 may include Ti, and the second metal layer 443 may include Cu. In an embodiment, the metal layer 440 may be formed to completely cover the upper surface of the second semiconductor chip 410 and the upper surface of the second molding layer 430.

Referring to FIG. 6G, in the result of FIG. 6F, a second carrier substrate C2 may be attached on the upper surface of the metal layer 440. The second carrier substrate C2 may be substantially the same as or similar to the first carrier substrate C1. After the second carrier substrate C2 is attached, the first carrier substrate C1 may be removed from the lower surface of the first redistribution structure 100. After the first carrier substrate C1 is removed, the external connection terminal 500 may be formed on the lower surface of the first redistribution structure 100.

Thereafter, in the result of FIG. 6G, as the second carrier substrate C2 may be removed, the semiconductor package 10 shown in FIG. 1 may be manufactured.

In the semiconductor package 10 according to an embodiment, a first semiconductor chip 210 may be mounted using the first carrier substrate C1, and then the second semiconductor chip 410 may be mounted separately. Accordingly, only a good die may be selected to be mounted as the first semiconductor chip 210 or the second semiconductor chip 410. Therefore, when mounting the first semiconductor chip 210 by a chip on wafer (COW) scheme using the second semiconductor chip 410 as a substrate, an additional process (for example, a dummy chip mounting process or the like) performed in the case where the second semiconductor chip 410 is a bad die may be limited and/or prevented from being performed, and thus the manufacturing cost of the semiconductor package 10 may be reduced.

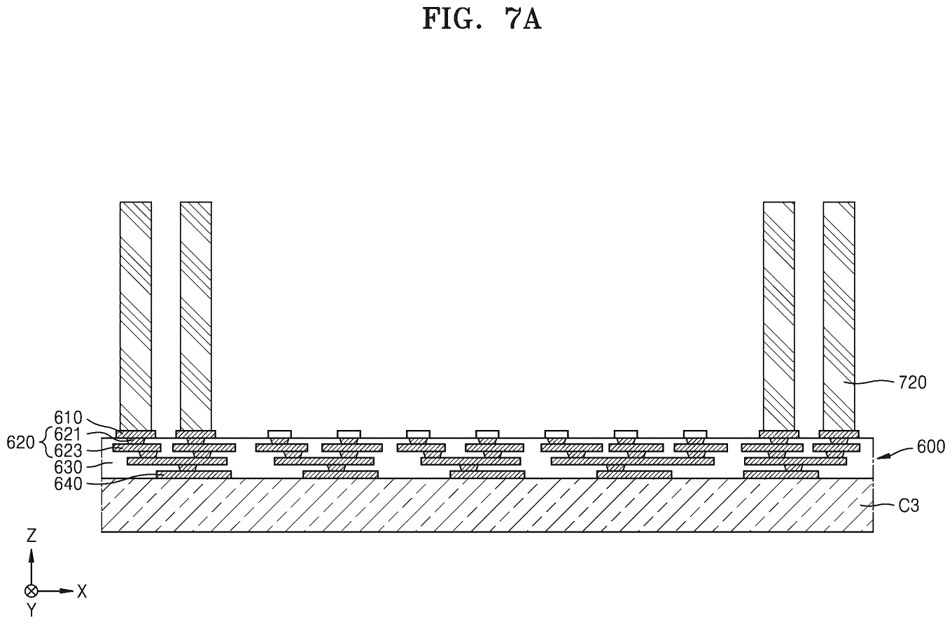

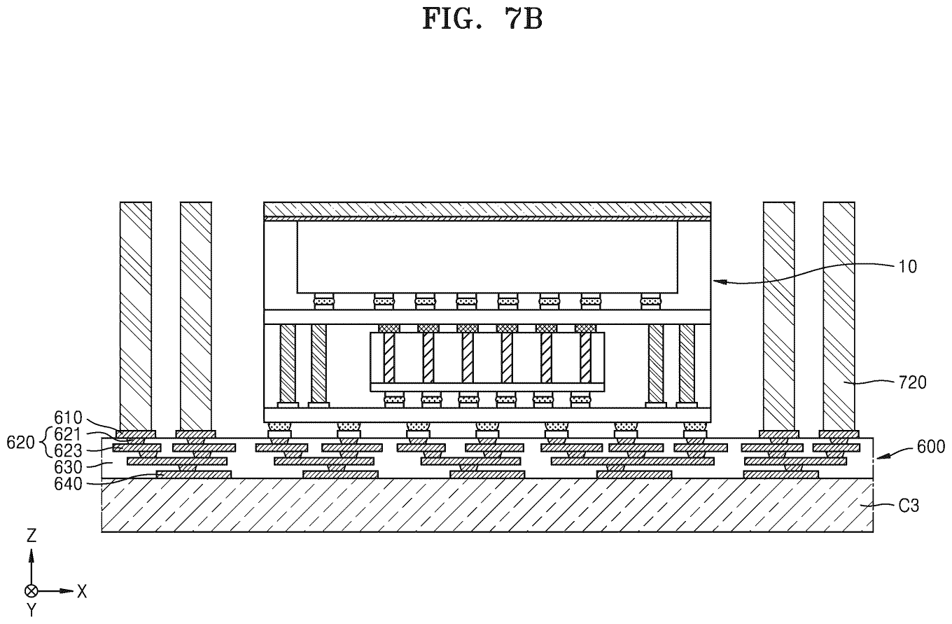

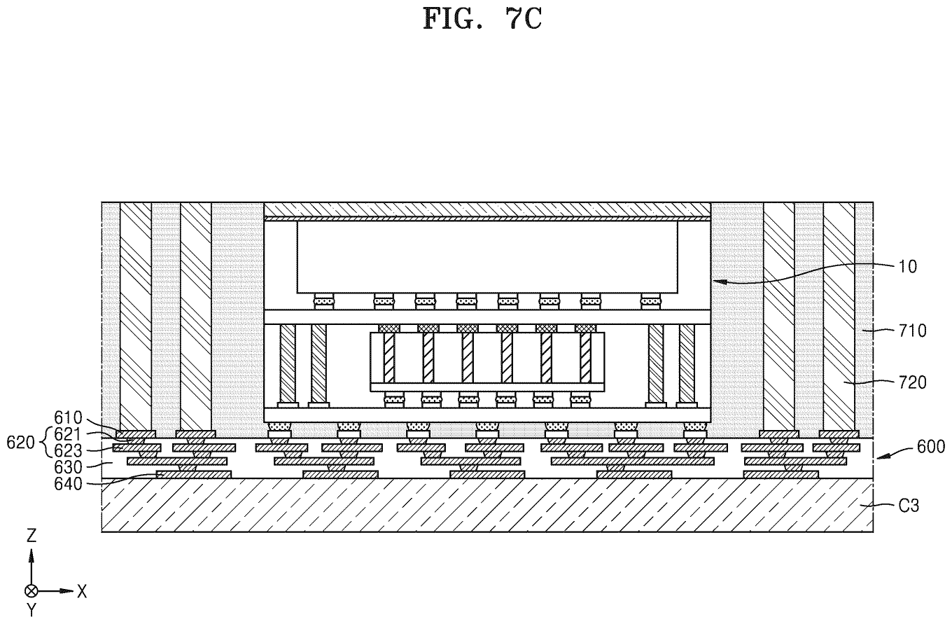

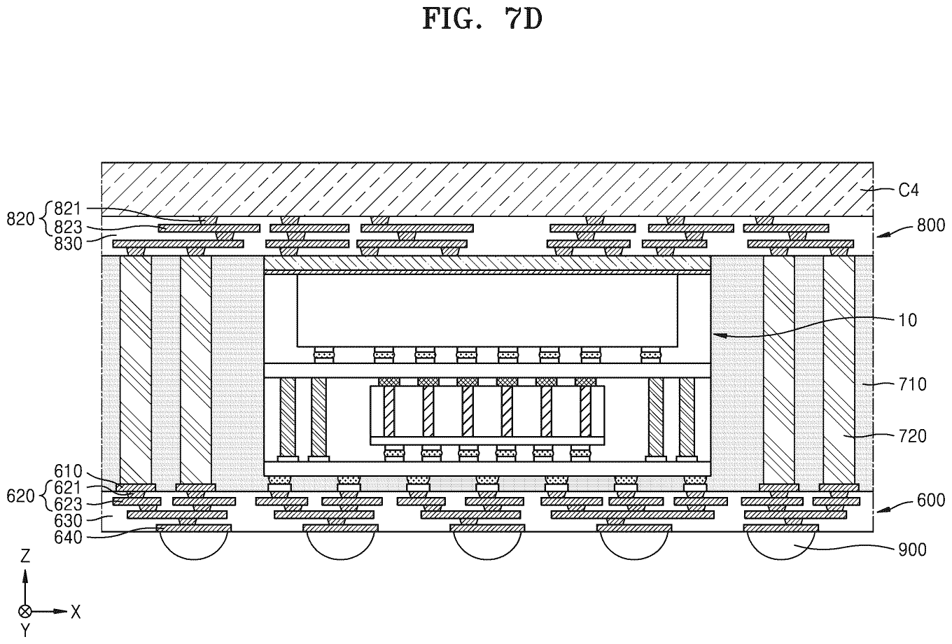

FIGS. 7A to 7D show cross-sectional views of respective steps in a method of manufacturing a semiconductor package 1000 according to an embodiment.

Referring to FIG. 7A, firstly a third carrier substrate C3 may be provided. The third carrier substrate C3 may be the same as or similar to the first carrier substrate C1. After the third carrier substrate C3 is provided, a lower redistribution structure 600 may be formed on the third carrier substrate C3. The lower redistribution structure 600 may be formed in the same manner as the formation of the first redistribution structure 100 described with reference to FIG. 6A. After the lower redistribution structure 600 is formed, the lower connection structures 720 may be formed on the lower redistribution structure 600. The lower connection structures 720 may be formed in the same manner as the formation of the first connection structure 240 described with reference to FIG. 6A.

Referring to FIG. 7B, in the result of FIG. 7A, the semiconductor package 10 may be mounted. The semiconductor package 10 may be mounted to the lower redistribution structure 600 through the external connection terminal 500 (see FIG. 1). As the external connection terminal 500 is coupled to the lower redistribution pads 610 and the UBM layers 140 (see FIG. 1), the semiconductor package 10 may be fixed on the lower redistribution structure 600.

Referring to FIG. 7C, in the result of FIG. 7B, the lower molding layer 710 may be formed on the lower redistribution structure 600. At this time, the lower molding layer 710 may cover the lower surface and opposite sidewalls of the semiconductor package 10. After the lower molding layer 710 is formed, a planarization process may be performed on the lower molding layer 710. As the planarization process is performed, the upper surface of the lower molding layer 710 may become coplanar with the upper surface of the semiconductor package 10. In an embodiment, the lower molding layer 710 may be made of a material different from that of at least one selected from the first molding layer 230 (see FIG. 1) and the second molding layer 430 (see FIG. 1).

Referring to FIG. 7D, in the result of FIG. 7C, the upper redistribution structure 800 may be formed on the semiconductor package 10 and the lower molding layer 710. The upper redistribution structure 800 may be formed in the same manner as the formation of the first redistribution structure 100 described with reference to FIG. 6A. After the upper redistribution structure 800 is formed, a fourth carrier substrate C4 may be attached on the upper redistribution structure 800. The fourth carrier substrate C4 may be substantially the same as or similar to the first carrier substrate C1. After the fourth carrier substrate C4 is attached, the third carrier substrate (C3) may be removed from the lower surface of the lower redistribution structure 600, and the external connection terminal 900 may be formed on the lower surface of the lower redistribution structure 600.

Thereafter, in the result of FIG. 7D, the fourth carrier substrate C4 is removed, and the upper redistribution pad 810 is formed, and thus the semiconductor package 1000 shown in FIGS. 4A and 4B may be manufactured.

In an embodiment, in the result of FIG. 7A, the semiconductor package 10a may also be mounted, unlike shown in FIG. 7B. Thereafter, procedures described with reference to FIGS. 7C to 7D may be sequentially performed to manufacture the semiconductor package 1000a shown in FIG. 4B.

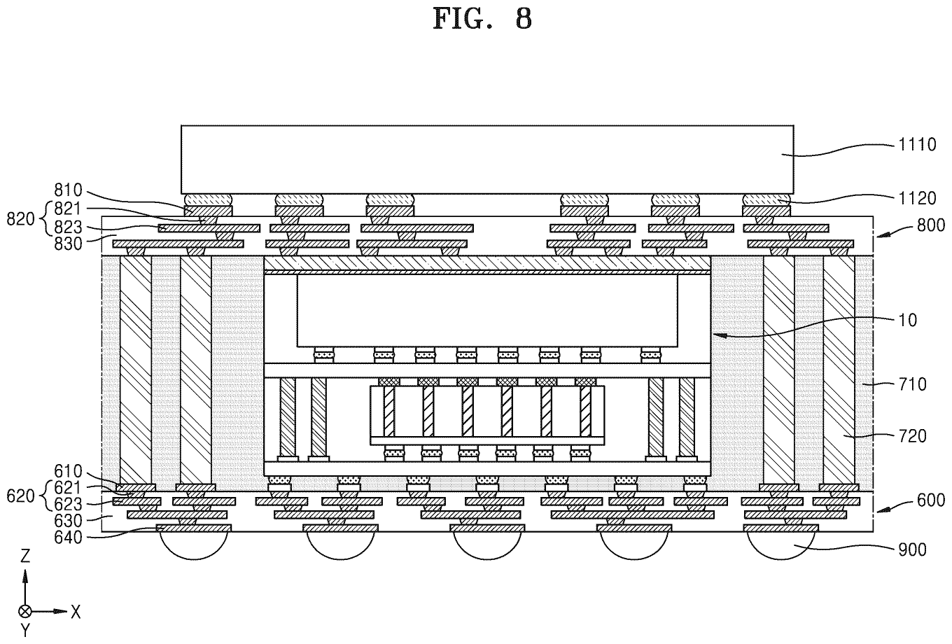

FIG. 8 shows a cross-sectional view of a method of manufacturing a semiconductor package 2000 according to an embodiment.

Referring to FIG. 8, in the result of FIG. 7D, after the fourth carrier substrate C4 is removed and the semiconductor package 1000 shown in FIG. 4A is manufactured, the upper semiconductor chip 1110 may be mounted on the upper redistribution structure 800. The upper semiconductor chip 1110 may be mounted to the upper redistribution structure 800 through the upper connection terminal 1120. Accordingly, the upper semiconductor chip 1110 may be fixed on the upper redistribution structure 800.

Thereafter, in the result of FIG. 8, the upper molding layer 1130 may be formed on the upper redistribution structure 800. At this time, the upper molding layer 1130 may cover the lower surface and opposite sidewalls of the upper semiconductor chip 1110. However, without being limited thereto, the upper molding layer 1130 may cover the upper surface, lower surface, and opposite sidewalls of the upper semiconductor chip 1110. As the upper molding layer 1130 is formed, the semiconductor package 2000 shown in FIG. 5 may be manufactured.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

1. A semiconductor package comprising:
a first redistribution structure;
a first semiconductor chip on the first redistribution structure;
a first molding layer covering the first semiconductor chip;
first connection structures on the first redistribution structure, the first connection structures extending in a vertical direction while passing through the first molding layer;
a second redistribution structure on the first semiconductor chip;
a second semiconductor chip on the second redistribution structure; and
a metal layer on the second semiconductor chip,
wherein the metal layer is in contact with an upper surface of the second semiconductor chip.

2. The semiconductor package of claim 1, wherein a horizontal area of the first semiconductor chip and a horizontal area of the second semiconductor chip are different from each other.

3. The semiconductor package of claim 1, wherein the metal layer extends in a horizontal direction beyond the second semiconductor chip.

4. The semiconductor package of claim 1, wherein
the metal layer includes a first metal layer and a second metal layer,
the first metal layer is on the second semiconductor chip, and the second metal layer is on the first metal layer.

5. The semiconductor package of claim 1, further comprising:
a second molding layer covering the second semiconductor chip.

6. The semiconductor package of claim 5, wherein the first molding layer and the second molding layer are made of different materials.

7. The semiconductor package of claim 1, wherein
the first redistribution structure includes a first redistribution via and a first redistribution line, and a horizontal width of the first redistribution via becomes larger closer to the first semiconductor chip.

8. The semiconductor package of claim 1, further comprising:
an underfill layer between the second semiconductor chip and the second redistribution structure.

9. The semiconductor package of claim 1, further comprising:
second connection structures between the first semiconductor chip and the second redistribution structure, wherein the second connection structures connect the first semiconductor chip to the second redistribution structure.

10. The semiconductor package of claim 1, wherein the first semiconductor chip includes a through electrode, the second semiconductor chip includes the through electrode, or both the first semiconductor chip and the second semiconductor chip each include the through electrode.

11. A semiconductor package comprising:
a lower redistribution structure;
a sub-semiconductor package on the lower redistribution structure;
a lower molding layer covering the sub-semiconductor package;
a lower connection structure on the lower redistribution structure and extending in a vertical direction while passing through the lower molding layer; and
an upper redistribution structure on the sub-semiconductor package, wherein
the sub-semiconductor package includes
a first redistribution structure,
a first semiconductor chip on the first redistribution structure,
a first molding layer surrounding the first semiconductor chip,
first connection structures on the first redistribution structure, the first connection structures extending in the vertical direction while passing through the first molding layer,
a second redistribution structure on the first semiconductor chip,
a second semiconductor chip on the second redistribution structure,
a second molding layer surrounding the second semiconductor chip, and
a metal layer on the second semiconductor chip, the metal layer being in contact with an upper surface of the second semiconductor chip.

12. The semiconductor package of claim 11, wherein the metal layer completely covers the upper surface of the second semiconductor chip and an upper surface of the second molding layer.

13. The semiconductor package of claim 11, wherein the first molding layer and the second molding layer are made of different materials.

14. The semiconductor package of claim 11, wherein the sub-semiconductor package further comprises an underfill layer between the second semiconductor chip and the second redistribution structure.

15. The semiconductor package of claim 11, wherein
the upper redistribution structure includes an upper redistribution via and an upper redistribution line, and
at least a portion of the upper redistribution via is in contact with the metal layer.

16. The semiconductor package of claim 11, wherein
a material of the lower molding layer is different than a material of the first molding layer, the material of the lower molding layer is different than a material of the second molding layer, or the material of the lower molding is different than both the material of the first molding layer and the material of the second molding layer.

17. The semiconductor package of claim 11, further comprising:
an upper semiconductor chip on the upper redistribution structure; and
an upper molding layer covering the upper semiconductor chip.

18. The semiconductor package of claim 17, wherein
the first semiconductor chip and the second semiconductor chip are logic chips, and
the upper semiconductor chip is a memory chip.

19. The semiconductor package of claim 17, wherein
a material of the upper molding layer is different than at least one of a material of the lower molding layer, a material the first molding layer, or a material of the second molding layer.

20. A semiconductor package comprising:
a first redistribution structure;
a first semiconductor chip on the first redistribution structure;
a first connection terminal between the first redistribution structure and the first semiconductor chip, the first connection terminal connecting the first redistribution structure and the first semiconductor chip;
a first molding layer covering the first semiconductor chip;
first connection structures on the first redistribution structure, the first connection structures extending in a vertical direction while passing through the first molding layer;
a second redistribution structure on the first semiconductor chip;
second connection structures between the first semiconductor chip and the second redistribution structure, the second connection structures electrically connecting the first semiconductor chip and the second redistribution structure to each other;
a second semiconductor chip on the second redistribution structure, the second semiconductor chip having a horizontal area larger than a horizontal area of the first semiconductor chip;
a second connection terminal between the second redistribution structure and the second semiconductor chip, the second connection terminal connecting the second redistribution structure and the second semiconductor chip to each other;
a second molding layer covering the second semiconductor chip; and
a metal layer on the second semiconductor chip,
the metal layer completely covering an upper surface of the second semiconductor chip and an upper surface of the second molding layer.

21-22. (canceled)
